(19) United States
(12) Patent Application Publication
(10) Pub. No.: US 2026/0019062 A1
(43) Pub. Date: Jan. 15, 2026

(54) PIEZOELECTRIC RESONATOR UNIT

(71) Applicant: Murata Manufacturing Co., Ltd., Nagaokakyo-shi (JP)

(72) Inventor: Sho FUKUYAMA, Nagaokakyo-shi (JP)

(21) Appl. No.: 19/328,370

(22) Filed: Sep. 15, 2025

Related U.S. Application Data
(63) Continuation of application No. PCT/JP2024/003845, filed on Feb. 6, 2024.

(30) Foreign Application Priority Data
Apr. 14, 2023 (JP) 2023-066114

(51) Int. Cl. H03H 9/13; H03H 9/19

(52) U.S. Cl. CPC H03H 9/132; H03H 9/19

(57) ABSTRACT

A piezoelectric resonator unit that includes: a piezoelectric resonator including a piezoelectric layer; a first substrate adjacent to a first principal surface of the piezoelectric layer; a first adhesion layer between the first substrate and the piezoelectric layer; a second substrate adjacent to a second principal surface of the piezoelectric layer; and a second adhesion layer between the second substrate and the piezoelectric layer. In plan view of the surface of the second substrate opposite from the piezoelectric layer, the second substrate includes a cut-away portion exposing an inclined portion of the second adhesion layer expanding toward an outer side portion of the second substrate and an extended end portion of an extended electrode on the piezoelectric layer. A connection electrode on the inclined portion of the second adhesion layer and the cut-away portion of the second substrate electrically connects an outer electrode and the extended end portion.

### CROSS REFERENCE TO RELATED APPLICATIONS

The present application is a continuation of International application No. PCT/JP2024/003845, filed Feb. 6, 2024, which claims priority to Japanese Patent Application No. 2023-066114, filed Apr. 14, 2023, the entire contents of each of which are incorporated herein by reference.

### TECHNICAL FIELD

The present disclosure relates to a piezoelectric resonator unit.

### BACKGROUND ART

Piezoelectric resonator units such as quartz crystal resonators having thickness-shear vibration as principal vibration are generally applied to reference signal sources included in oscillating devices, band-pass filters, and the like. Such piezoelectric resonator units are demanded to be improved in vibration characteristics or electrical characteristics.

Patent Document 1 exemplarily discloses a method of manufacturing a piezoelectric device, the method including preparing a base wafer, preparing a piezoelectric wafer including a plurality of piezoelectric frames, joining the piezoelectric wafer and the base wafer by an adhesive agent, removing an adhesive agent exposed through a through hole so as to expose an extended electrode provided in the piezoelectric frames, forming a connection electrode connected to the extended electrode so as to cover a bottom surface of the base wafer opposite from a surface joined to the piezoelectric wafer, a side surface of the through hole, a side surface of the adhesive agent, and the extended electrode.

Patent Document 2 exemplarily discloses a method of manufacturing a piezoelectric vibration device, the method including preparing a piezoelectric wafer including a plurality of piezoelectric frames, forming an excitation electrode, an extended electrode, and a first side-surface electrode electrically connected to each other on each of the piezoelectric frames of the piezoelectric wafer, preparing two flat-plate wafers including a plurality of flat plates, forming an outer electrode and a second side-surface electrode electrically connected to the outer electrode on each of the flat plates, bonding each of the two flat-plate wafers to a corresponding principal surface of the piezoelectric wafer with a nonconductive sealing layer interposed therebetween, and forming a connection electrode electrically connecting the first side-surface electrode and the second side-surface electrode after bonding.

Patent Document 3 exemplarily discloses a piezoelectric resonator unit including a substrate and a piezoelectric vibration plate bonded with a metal adhesion layer interposed therebetween, and a connection electrode provided on a surface of the metal adhesion layer and connecting an outer electrode provided on the substrate and an excitation electrode provided on the piezoelectric vibration plate.
Patent Document 1: Japanese Unexamined Patent Application Publication No. 2011-176787
Patent Document 2: Japanese Unexamined Patent Application Publication No. 2012-015824
Patent Document 3: Japanese Unexamined Patent Application Publication No. 2000-223997

### SUMMARY OF THE DISCLOSURE

However, both Patent Document 1 and Patent Document 2 fail to consider possible deterioration in the resonant frequency characteristics of a quartz crystal resonator due to influences of a formation state of an adhesion layer, e.g., whether the adhesion layer dents from outer peripheral surfaces of a piezoelectric resonator and a substrate or whether the adhesion layer has a section bulging to be rounded affects formation states such as film thickness and a formation range of the connection electrode to be formed on a surface of the adhesion layer. Furthermore, Patent Document 3 fails to consider risks of unstable frequency characteristics of the piezoelectric resonator unit due to transmission of stress from the substrate to the piezoelectric vibration plate via the metal adhesion layer bonding the substrate and the piezoelectric vibration plate.

The present disclosure has been achieved in view of such circumstances, and an object of the present disclosure is to provide a piezoelectric resonator unit that is simply configured, stabilizes frequency characteristics, reduces defective connection between electrodes due to defective formation of a connection electrode, and improves resonant frequency stability.

According to an aspect of the present disclosure, a piezoelectric resonator unit includes: a piezoelectric resonator including a piezoelectric layer having a first principal surface and a second principal surface facing each other in a thickness direction of the piezoelectric layer, a first excitation electrode on the first principal surface, a second excitation electrode on the second principal surface, a first extended electrode electrically connected to the first excitation electrode and extended to a peripheral edge portion of the first principal surface of the piezoelectric layer, and a second extended electrode electrically connected to the second excitation electrode and extended to a peripheral edge portion of the second principal surface of the piezoelectric layer; a first substrate adjacent to the first principal surface of the piezoelectric layer; a first adhesion layer interposed between the first substrate and the piezoelectric layer; a second substrate adjacent to the second principal surface of the piezoelectric layer; and a second adhesion layer interposed between the second substrate and the piezoelectric layer, wherein the second substrate includes a first outer electrode in a peripheral edge portion on a surface opposite from the piezoelectric layer, in plan view of the surface of the second substrate opposite from the piezoelectric layer, the second substrate includes a first cut-away portion exposing a first inclined portion of the second adhesion layer expanding toward an outer side portion of the second substrate and a first extended end portion of one of the first extended electrode or the second extended electrode; and a first connection electrode on the first inclined portion of the second adhesion layer and the first cut-away portion of the second substrate that electrically connects the first outer electrode and the first extended end portion of the one of the first extended electrode or the second extended electrode.

The present disclosure can provide a piezoelectric resonator unit that is simply configured, stabilizes frequency characteristics, reduces defective connection between electrodes due to defective formation of a connection electrode, and improves resonant frequency stability.

### BRIEF DESCRIPTION OF THE DRAWINGS

FIG. 1 is an exploded perspective view of a quartz crystal resonator unit according to a first embodiment.

FIG. 2 is a sectional view taken along line II-II in FIG. 1.

FIG. 3 is an explanatory view on connection relations between electrodes of the quartz crystal resonator unit according to the first embodiment.

FIG. 4 is an explanatory view on a method of manufacturing the quartz crystal resonator unit according to the first embodiment.

FIG. 5 is an explanatory view on connection relations between electrodes of a quartz crystal resonator unit according to a second embodiment.

FIG. 6 is an explanatory view on connection relations between electrodes of a quartz crystal resonator unit according to a third embodiment.

FIG. 7 is an explanatory view on modified disposition of a shield electrode on a first substrate of the quartz crystal resonator unit according to the third embodiment.

FIG. 8 is an explanatory view on connection relations between electrodes of a quartz crystal resonator unit according to a fourth embodiment.

FIG. 9 is an explanatory view on modified disposition of a shield electrode on a first substrate of the quartz crystal resonator unit according to the fourth embodiment.

FIG. 10 is an explanatory view on connection relations between electrodes of a quartz crystal resonator unit according to a fifth embodiment.

FIG. 11 is an explanatory view on a method of manufacturing the quartz crystal resonator unit according to the fifth embodiment.

FIG. 12 is an explanatory view on the method of manufacturing the quartz crystal resonator unit according to the fifth embodiment.

FIG. 13 is an explanatory view on connection relations between electrodes of a quartz crystal resonator unit according to a sixth embodiment.

FIG. 14 is an explanatory view on connection relations between electrodes of a quartz crystal resonator unit according to a seventh embodiment.

FIG. 15 is an explanatory view on the connection relations between the electrodes of the quartz crystal resonator unit according to the seventh embodiment.

### DESCRIPTION OF THE PREFERRED EMBODIMENTS

Description is made hereinafter to embodiments of the present disclosure. In the following drawings, identical or similar constituent elements will be denoted by identical or similar reference signs. The drawings are provided exemplarily, sizes and shapes of respective portions are illustrated schematically, and technical scopes of the present disclosure are not comprehended limitedly to the embodiments.

### First Embodiment

### <Outline of Quartz Crystal Resonator Unit 1>

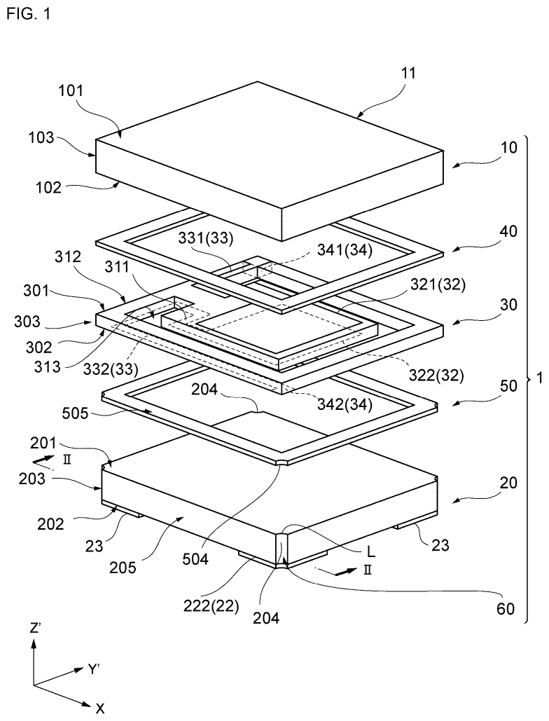

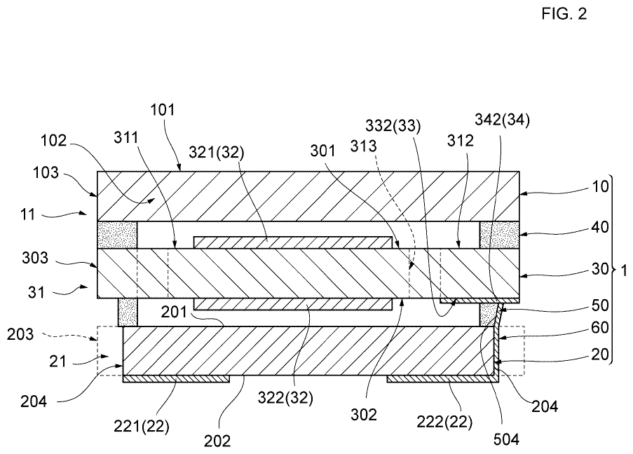

With reference to FIGS. 1 and 2, the quartz crystal resonator unit 1 according to the first embodiment will initially be described in terms of a configuration thereof. FIG. 1 is an exploded perspective view of the configuration of the quartz crystal resonator unit 1. FIG. 2 is a sectional view taken along line II-II in FIG. 1. FIGS. 1 and 2 are schematic views illustrating connection relations between electrodes of the quartz crystal resonator unit 1, and not illustrating actual shapes of constituent components of the quartz crystal resonator unit 1.

The quartz crystal resonator unit 1 exemplifies a piezoelectric resonator unit. As illustrated in FIGS. 1 and 2, the quartz crystal resonator unit 1 includes a first substrate 10, a second substrate 20, a quartz crystal resonator 30, a first adhesion layer 40 interposed between the first substrate 10 and the quartz crystal resonator 30, a second adhesion layer 50 interposed between the second substrate 20 and the quartz crystal resonator 30, and a pair of connection electrodes 60 provided on an outer peripheral surface of the quartz crystal resonator unit 1.

The first substrate 10, the second substrate 20, and the quartz crystal resonator 30 each have a plate shape. The first adhesion layer 40 has a frame shape corresponding to an outer shape of the first substrate 10, whereas the second adhesion layer 50 has a frame shape corresponding to an outer shape of the second substrate 20. As illustrated in FIG. 2, the first substrate 10 and the second substrate 20 are bonded to principal surfaces (a first principal surface 301 and a second principal surface 302 to be described later) in a thickness direction of the plate shape of the quartz crystal resonator 30 with the first adhesion layer 40 and the second adhesion layer 50 interposed therebetween, respectively.

The quartz crystal resonator unit 1 is mounted on an external substrate (not shown) configured to supply the quartz crystal resonator unit 1 with input/output signals. The second substrate 20 and the quartz crystal resonator 30 are each provided with an electrode for transmission and the like of input/output signals supplied from the external substrate. The pair of connection electrodes 60 are provided on the outer peripheral surface of the quartz crystal resonator unit 1 so as to electrically connect the electrodes provided on the quartz crystal resonator 30 and the second substrate 20. The quartz crystal resonator unit 1 is mounted on the external substrate such that the electrode provided on the second substrate 20 is mounted on the external substrate.

A state where the constituent components of the quartz crystal resonator unit 1 are assembled to complete the quartz crystal resonator unit 1 may hereinafter be referred to as “assembled state”. In the assembled state, both a thickness direction of the quartz crystal resonator unit 1 and thickness directions of the constituent components of the quartz crystal resonator unit 1 match a Z′ axis direction illustrated in FIG. 1.

### <Details of Quartz Crystal Resonator Unit 1>

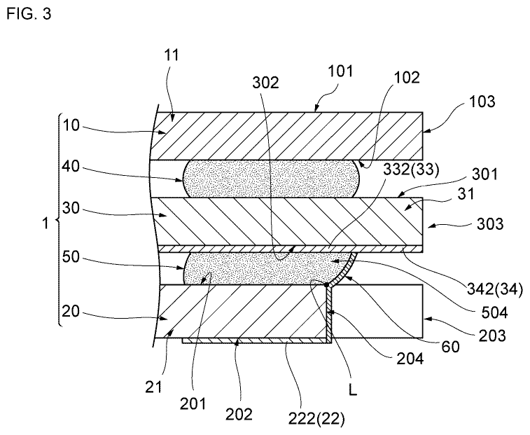

The constituent components of the quartz crystal resonator unit 1 will be described in detail next with reference to FIGS. 1 to 3. FIG. 3 is an explanatory view on connection relations between the electrodes of the quartz crystal resonator unit 1. The quartz crystal resonator 30, the first substrate 10, the second substrate 20, the second adhesion layer 50, the first adhesion layer 40, and the connection electrodes 60 will be described hereinafter in the mentioned order.

### (Quartz Crystal Resonator 30)

The quartz crystal resonator 30 exemplifies a piezoelectric resonator. The quartz crystal resonator 30 includes a quartz crystal body 31, and an electrode pattern formed on the quartz crystal body 31. The electrode pattern on the quartz crystal resonator 30 includes a pair of excitation electrodes 32, and a pair of extended electrodes 33 electrically connected to the pair of excitation electrodes 32.

The quartz crystal body 31 exemplifies a piezoelectric layer. Examples of the quartz crystal body 31 include an AT-cut quartz crystal substrate. When quartz crystal has crystal axes including an X axis, a Y axis, and a Z axis and axes obtained by rotating the Y axis and the Z axis about the X axis from the Y axis toward the Z axis by 35 degrees 15 minutes±1 minute 30 seconds are defined as Y′ axis and Z′ axis, the AT-cut quartz crystal substrate is cut from synthetic quartz crystal assuming that a plane parallel to a plane specified by the X axis and the Y′ axis (hereinafter, referred to as “XY′ plane”; the same or a similar applies to any plane specified by other axes) is a principal surface. The quartz crystal resonator 30 adopting the quartz crystal body 31 thus AT cut has principal vibration in a thickness-shear vibration mode. The quartz crystal body 31 has unlimited cut-angles, and may alternatively be BT cut, GT cut, SC cut, or the like.

The quartz crystal body 31 has a plate shape. The quartz crystal body 31 includes the first principal surface 301 and the second principal surface 302 provided on respective sides in a thickness direction of the plate shape, and an element outer peripheral surface 303 constituting a side surface of the plate shape. In plan view of any one of the principal surfaces of the quartz crystal body 31, the quartz crystal body 31 includes a center portion 311, a peripheral edge portion 312 surrounding the center portion 311, and a penetrating portion 313 interposed between the center portion 311 and the peripheral edge portion 312.

The center portion 311 principally functions as a vibration portion configured to execute thickness-shear vibration of the quartz crystal resonator 30. The peripheral edge portion 312 supports the center portion 311. The penetrating portion 313 is a slot penetrating the quartz crystal body 31 in the thickness direction. The penetrating portion 313 causes the peripheral edge portion 312 to support the center portion 311 and decreases restraint force of the peripheral edge portion 312 to vibration of the center portion 311, so as to improve resonant frequency stability of the center portion 311.

When voltage is applied, the pair of excitation electrodes 32 cause thickness-shear vibration of the center portion 311. As illustrated in FIG. 2, the pair of excitation electrodes 32 include a first excitation electrode 321 provided in a center region adjacent to the first principal surface 301 of the center portion 311, and a second excitation electrode 322 provided in a center region adjacent to the second principal surface 302 of the center portion 311. In other words, the first excitation electrode 321 and the second excitation electrode 322 are provided at corresponding positions on the first principal surface 301 and the second principal surface 302 to interpose the center portion 311. Hereinafter, the first excitation electrode 321 and the second excitation electrode 322 may be referred to as “excitation electrodes 32” when distinction therebetween is not necessary. The same or a similar applies to the other constituent components of the quartz crystal resonator unit 1.

The excitation electrodes 32 are metal films made of a same material. For example, the excitation electrodes 32 may include an underlying chrome (Cr) layer and a gold (Au) layer further provided on a surface of the chrome layer. The other electrodes of the quartz crystal resonator 30 are made of the same materials as those of the excitation electrodes 32. The electrodes of the quartz crystal resonator unit 1 may alternatively be made of different materials.

The pair of extended electrodes 33 are electrically connected to the pair of excitation electrodes 32 and are provided in the peripheral edge portion 312 of the quartz crystal body 31 so as to extend the pair of excitation electrodes 32 to the peripheral edge portion 312 of the quartz crystal body 31. Specifically, the pair of extended electrodes 33 include a first extended electrode 331 electrically connected to the first excitation electrode 321 and provided to extend across the first principal surface 301, the element outer peripheral surface 303, and the second principal surface 302 in the peripheral edge portion 312, and a second extended electrode 332 electrically connected to the second excitation electrode 322 and provided on the second principal surface 302 in the peripheral edge portion 312.

Portions of the first extended electrode 331 and the second extended electrode 332, the portions being provided on the second principal surface 302, include a first extended end portion 341 and a second extended end portion 342 provided at two corner portions on a diagonal line of the second principal surface 302 in the peripheral edge portion 312. Hereinafter, the first extended end portion 341 and the second extended end portion 342 may be collectively referred to as “pair of extended end portions 34”.

### (First Substrate 10)

The first substrate 10 includes a first substrate body 11. The first substrate 10 may further include an electrode such as a shield electrode formed on the first substrate body 11.

The first substrate body 11 has a plate shape. The first substrate body 11 includes a principal surface 101 and a principal surface 102 provided on respective sides in a thickness direction of the plate shape, and a first outer peripheral surface 103 constituting a side surface of the plate shape. In the assembled state, the first substrate 10 is bonded to the first principal surface 301 of the quartz crystal resonator 30 with the first adhesion layer 40 interposed therebetween such that the principal surface 102 faces the first principal surface 301 of the quartz crystal resonator 30. In plan view of the principal surface 101, a shape of the first outer peripheral surface 103 in plan view is overlapped with a shape of the element outer peripheral surface 303 of the quartz crystal resonator 30 in plan view.

The first substrate body 11 is made of glass or quartz crystal. The first substrate body 11 may alternatively be made of any other optically transparent material or a semiconductor material such as silicon. When the first substrate body 11 is made of a semiconductor material, the semiconductor material can be provided with an integrated circuit constituting an oscillator circuit.

### (Second Substrate 20)

The second substrate 20 includes a second substrate body 21, and an electrode pattern formed on the second substrate body 21. The electrode pattern on the second substrate body 21 includes a pair of outer electrodes 22 configured to transmit input/output signals from the external substrate to different electrodes of the quartz crystal resonator unit 1, and two outer electrodes 23 configured not to transmit input/output signals from the external substrate to different electrodes of the quartz crystal resonator unit 1.

The second substrate body 21 has a plate shape. The second substrate body 21 includes a principal surface 201 and a principal surface 202 provided on respective sides in a thickness direction of the plate shape, and a second outer peripheral surface 203 constituting a side surface of the plate shape. The principal surface 202 exemplifies a surface opposite from the quartz crystal body 31. In the assembled state, the second substrate 20 is bonded to the second principal surface 302 of the quartz crystal resonator 30 with the second adhesion layer 50 interposed therebetween such that the principal surface 201 faces the second principal surface 302 of the quartz crystal resonator 30.

The second outer peripheral surface 203 includes two cut-away portions 204 provided at corner portions corresponding to the pair of extended end portions 34, and an outer peripheral surface portion 205 connected to the two cut-away portions 204. In plan view of the principal surface 202 of the second substrate body 21 in the assembled state, the cut-away portions 204 are formed to expose portions of the second adhesion layer 50 (inclined portions 504 of the second adhesion layer 50 to be described later) corresponding to the cut-away portions 204, and the extended end portions 34 of the extended electrodes 33 on the second substrate 20. In other words, each of the extended end portions 34 is positioned closer to the outer peripheral surface of the quartz crystal resonator unit 1 than a ridge portion L of the cut-away portion 204. The outer peripheral surface portion 205 has a shape in plan view overlapped with the shape of the element outer peripheral surface 303 in plan view.

The second substrate body 21 is made of a material identical or similar to the material for the first substrate body 11, namely, glass or quartz crystal. The second substrate body 21 may alternatively be made of a material different from the material for the first substrate body 11, such as any other optically transparent material or a semiconductor material such as silicon.

The pair of outer electrodes 22 and the two outer electrodes 23 are provided at four corner portions in a peripheral edge portion of the principal surface 202 of the second substrate body 21. The pair of outer electrodes 22 exemplify electrodes to be mounted on the external substrate. The pair of outer electrodes 22 are provided at the corner portions of the principal surface 202, the corner portions corresponding to the pair of extended end portions 34 (i.e., corner portions corresponding to the two cut-away portions 204). Specifically, the pair of outer electrodes 22 include a first outer electrode 221 corresponding to the first extended end portion 341, and a second outer electrode 222 corresponding to the second extended end portion 342. The two outer electrodes 23 are provided at the other corner portions of the principal surface 202. The pair of outer electrodes 22 and the two outer electrodes 23 may each be provided thereon with a solder bump (not shown) for mounting the quartz crystal resonator unit 1 on the external substrate.

In the assembled state, the pair of outer electrodes 22 are electrically connected to the pair of extended end portions 34 of the quartz crystal resonator 30 by the pair of connection electrodes 60. In this manner, the pair of outer electrodes 22 are electrically connected to the pair of excitation electrodes 32 via the pair of connection electrodes 60 and the pair of extended end portions 34. The pair of outer electrodes 22 are electrically connected also to an electronic element on the external substrate by soldering.

The two outer electrodes 23 are not supplied with any input/output signal from the electronic element on the external substrate. At least one of the two outer electrodes 23 may be a ground electrode configured to be supplied with ground potential.

### (Second Adhesion Layer 50)

The second adhesion layer 50 exemplifies a bonding material functioning as an adhesion material bonding the second substrate 20 to the second principal surface 302 of the quartz crystal resonator 30 and functioning as a sealing frame sealing a space between the second substrate 20 and the quartz crystal resonator 30. The second adhesion layer 50 includes the two inclined portions 504 corresponding to the two cut-away portions 204 in the second outer peripheral surface 203 of the second substrate 20, and a connection portion 505 connected to the two inclined portions 504.

As illustrated in FIG. 3, each of the inclined portions 504 has a surface inclined toward an outer side portion of the second adhesion layer 50 from the ridge portion L between the cut-away portion 204 and the principal surface 201 of the second substrate 20. In plan view of the principal surface 202 of the second substrate body 21 in the assembled state, the inclined portion 504 is formed to expand toward an outer side portion of the second substrate 20 and exposed from the cut-away portion 204. The shape of the outer peripheral surface portion 205 in plan view is overlapped with the shape of the element outer peripheral surface 303 in plan view, so that the connection portion 505 is not formed into a slope like the inclined portions 504 but is formed to have a rounded side surface coupling the outer peripheral surface portion 205 and the element outer peripheral surface 303.

The second adhesion layer 50 is formed exemplarily by thermosetting a resin adhesive agent in a pressurized and heated state. Each of the inclined portions 504 of the second adhesion layer 50 thus has a shape determined in accordance with bonding conditions such as a quantity of the resin adhesive agent to be applied, an applied pressure upon bonding the first substrate 10 to the quartz crystal resonator 30 (i.e., a pressure applied to the resin adhesive agent), and shapes of the first outer peripheral surface 103 of the first substrate 10 and the element outer peripheral surface 303 of the quartz crystal resonator 30. Formation of the inclined portions 504 is described in a method of manufacturing the quartz crystal resonator unit 1.

### (First Adhesion Layer 40)

The first adhesion layer 40 exemplifies a bonding material functioning as an adhesion material bonding the first substrate 10 to the first principal surface 301 of the quartz crystal resonator 30 and functioning as a sealing frame sealing a space between the first substrate 10 and the quartz crystal resonator 30. The first adhesion layer 40 is formed similarly to the second adhesion layer 50, by thermosetting a resin adhesive agent in a pressurized and heated state.

### (Connection Electrode 60)

The pair of connection electrodes 60 exemplify electrodes configured to electrically connect the pair of excitation electrodes 32 and the pair of outer electrodes 22. As illustrated in FIG. 3, each of the connection electrodes 60 is provided on the cut-away portion 204 and the inclined portion 504 so as to electrically connect the outer electrode 22 and the extended end portion 34 of the extended electrode 33. The connection electrodes 60 electrically connect the excitation electrodes 32 to the pair of outer electrodes 22 via the connection electrodes 60 and the extended electrodes 33. Each of the connection electrodes 60 has a surface that may be covered with a plating film (not shown).

### <Method of Manufacturing Quartz Crystal Resonator Unit 1>

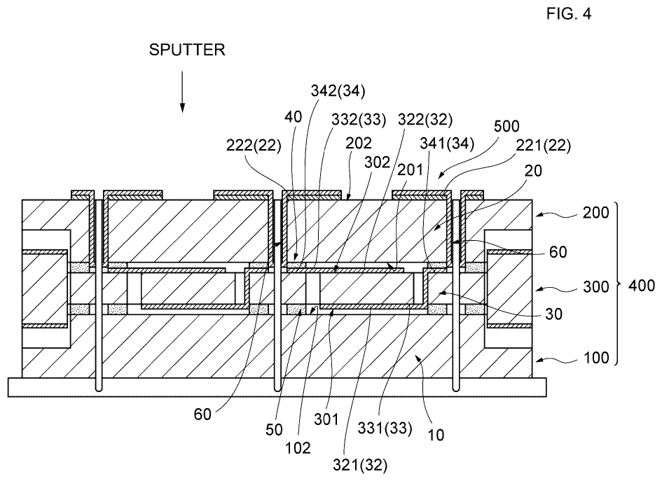

With reference to FIGS. 1 to 4, description is subsequently made to an exemplary method of manufacturing the quartz crystal resonator unit 1. The quartz crystal resonator unit 1 may alternatively be manufactured in accordance with any other method. As illustrated in FIG. 4, the quartz crystal resonator unit 1 is herein formed in a wafer including a plurality of quartz crystal resonator units 1. Hereinafter, wafers corresponding to the first substrate 10, the second substrate 20, and the quartz crystal resonator 30 of the quartz crystal resonator unit 1 will be referred to as “first substrate wafer 100”, “second substrate wafer 200”, and “piezoelectric wafer 300”, respectively, an adhesion body in which the “first substrate wafer 100”, the “second substrate wafer 200”, and the “piezoelectric wafer 300” are bonded will be referred to as “wafer adhesion body 400”, and each of the quartz crystal resonator units 1 not yet provided with part of the electrodes in the wafer adhesion body 400 will be referred to as “adhesion body 500”.

Initially prepared are the first substrate wafer 100, the second substrate wafer 200, and the piezoelectric wafer 300. Each of the second substrates 20 included in the second substrate wafer 200 is provided with the cut-away portions 204. Each of the quartz crystal resonators 30 included in the piezoelectric wafer 300 is provided with the excitation electrodes 32 and the extended electrodes 33.

Subsequently, the first substrate wafer 100 and the piezoelectric wafer 300 are bonded to each other. Specifically, a resin adhesive agent is applied to a peripheral edge portion of the first principal surface 301 of each of the quartz crystal resonators 30 included in the piezoelectric wafer 300, and each of the first principal surfaces 301 of the piezoelectric wafer 300 is then directed to each of the principal surfaces 102 of the first substrate wafer 100 and is bonded to the first substrate wafer 100 in a pressurized state. The resin adhesive agent is then thermoset to form the first adhesion layer 40 interposed between each of the first substrates 10 in the first substrate wafer 100 and each of the quartz crystal resonators 30 in the piezoelectric wafer 300. The first adhesion layer 40 integrally bonds each of the first substrate 10 and each of the quartz crystal resonators 30.

Subsequently, the piezoelectric wafer 300 and the second substrate wafer 200 are bonded to each other. Specifically, in order to form the inclined portions 504 after the resin adhesive agent is thermoset, a predetermined quantity of a resin adhesive agent is applied to a peripheral edge portion of the second principal surface 201 of each of the second substrates 20 in the second substrate wafer 200, and each of the second principal surfaces 201 of the second substrate wafer 200 is then directed to each of the second principal surfaces 302 of the piezoelectric wafer 300 and is bonded to the piezoelectric wafer 300 in a predetermined pressurized state. The resin adhesive agent is then thermoset to form the second adhesion layer 50 including the inclined portions 504 and interposed between each of the second substrates 20 in the second substrate wafer 200 and each of the quartz crystal resonators 30 in the piezoelectric wafer 300. The second adhesion layer 50 integrally bonds each of the first substrate 10 and each of the quartz crystal resonators 30. Then formed is the wafer adhesion body 400 including a plurality of adhesion bodies 500.

Detailed description is hereinafter made to formation of the inclined portions 504 of the second adhesion layer 50. Application of a certain pressure to the resin adhesive agent interposed between the second substrate 20 and the quartz crystal resonator 30 decreases a distance between the second substrate 20 and the quartz crystal resonator 30. Part of the resin adhesive agent expands toward outer peripheral surfaces of the second substrate 20 and the quartz crystal resonator 30. As described above, each of the extended end portions 34 is positioned closer to the outer peripheral surface of the quartz crystal resonator unit 1 than the ridge portion L of the cut-away portion 204. A portion of the resin adhesive agent expanding along the principal surface 201 of the second substrate 20 (hereinafter, referred to as “second portion of the resin adhesive agent”) having reached the ridge portion L of the cut-away portion 204 is provided with no more surface to extend therealong. The second portion of the resin adhesive agent stops expanding at the ridge portion L of the cut-away portion 204. In contrast, even though the second portion of the resin adhesive agent stops expanding at the ridge portion L of the cut-away portion 204, a portion of the resin adhesive agent expanding along the second principal surface 302 of the quartz crystal resonator 30 (hereinafter, referred to as “first portion of the resin adhesive agent”) keeps expanding along the second principal surface 302 of the quartz crystal resonator 30 if continuously pressurized. When the first portion of the resin adhesive agent reaches the extended end portion 34, the resin adhesive agent is no more pressurized. In this case, part of the resin adhesive agent constitutes a portion having a surface inclined toward the outer side portion of the second substrate 20 from the ridge portion L of the cut-away portion 204. The resin adhesive agent is then heated to be thermoset, and such an inclined portion constitutes the inclined portion 504. The second adhesion layer 50 including the inclined portions 504 is completed in this manner.

The shape of the outer peripheral surface portion 205 in plan view is overlapped with the shape of the element outer peripheral surface 303 in plan view. When the resin adhesive agent corresponding to the outer peripheral surface portion 205 is pressurized, both side portions in contact with the principal surface 201 of the second substrate 20 and the second principal surface 302 of the quartz crystal resonator 30 can thus extend uniformly along the principal surface 201 and the second principal surface 302. In accordance with surface tension of the resin adhesive agent corresponding to the outer peripheral surface portion 205 and other bonding conditions, a portion of the resin adhesive agent corresponding to the outer peripheral surface portion 205 and interposed between the principal surface 201 of the second substrate 20 and the second principal surface 302 of the quartz crystal resonator 30 bulges or dents to be rounded from the both side portions of the resin adhesive agent. As a result, the connection portion 505 corresponding to the outer peripheral surface portion 205 is not formed into a slope like the inclined portions 504 but is formed to have a rounded side surface coupling the outer peripheral surface portion 205 and the element outer peripheral surface 303.

Description returns to the method of manufacturing the quartz crystal resonator unit 1. After the wafer adhesion body 400 is formed, each of the adhesion bodies 500 in the wafer adhesion body 400 is provided with the outer electrodes 22 and the outer electrodes 23, as well as the connection electrodes 60 electrically connected to the outer electrodes 22. Specifically, sputtering or vacuum deposition is applied to the principal surface 202 of each of the second substrates 20 in the wafer adhesion body 400.

As described above, in plan view of the principal surface 202 of the second substrate 20, the cut-away portions 204 of the second substrate 20 are formed to expose the inclined portions 504 of the second adhesion layer 50 corresponding to the cut-away portions 204 of the second substrate 20 and the extended end portions 34 of the extended electrodes 33 on the second substrate 20. Upon application of sputtering or vacuum deposition, metal films constituting the electrodes can thus be formed on surfaces of the cut-away portions 204 of the second substrate 20, the inclined portions 504 of the second adhesion layer 50, and the extended end portions 34, corresponding to positions provided with the outer electrodes 22. The connection electrodes 60 can then electrically connect the outer electrodes 22 and the extended end portions 34 of the extended electrodes 33. As a result, the outer electrodes 22 on the second substrate 20 can be electrically connected to the excitation electrodes 32 of the quartz crystal resonator 30 via the connection electrodes 60 and the extended electrodes 33.

Plating films (not shown) are thereafter formed on surfaces of the connection electrodes 60, the outer electrodes 22, and the outer electrodes 23, as well as the surfaces of the extended end portions 34 bulging from the second adhesion layer 50, to complete manufacture of the plurality of quartz crystal resonator units 1 included in the wafer. Alternatively, only part of the surfaces of the extended end portions 34 bulging from the second adhesion layer 50 may be provided with the plating films.

Description has been made above to the exemplary first embodiment of the present disclosure.

According to an embodiment of the present disclosure, the quartz crystal resonator unit 1 includes the quartz crystal resonator 30 exemplifying a piezoelectric resonator including the quartz crystal body 31 exemplifying a piezoelectric layer, the excitation electrodes 32 provided on the first principal surface 301 and the second principal surface 302 on the both sides in the thickness direction of the quartz crystal body 31, the extended electrodes 33 electrically connected to the excitation electrodes 32 and extended to the peripheral edge portion of the second principal surface 302 of the quartz crystal body 31, the first substrate 10 provided adjacent to the first principal surface 301 of the quartz crystal body 31, the first adhesion layer 40 interposed between the first substrate 10 and the quartz crystal body 31, the second substrate 20 provided adjacent to the second principal surface 302 of the quartz crystal body 31, and the second adhesion layer 50 interposed between the second substrate 20 and the quartz crystal body 31. The second substrate 20 includes the outer electrodes 22 provided at the four corner portions of the peripheral edge portion of the principal surface 202 opposite from the quartz crystal body 31 and electrically connected to the extended electrodes 33. In plan view of the principal surface 202, the second substrate 20 includes cut-away portions 204 exposing the inclined portions 504 of the second adhesion layer 50 expanding toward the outer side portion of the second substrate 20, and the extended end portions 34 of the extended electrodes 33. The inclined portions 504 of the second adhesion layer 50 and the cut-away portions 204 are provided with the connection electrodes 60 electrically connecting the outer electrodes 22 and the extended end portions 34.

In this manner, the inclined portions 504 of the second adhesion layer 50 are each simply configured, so that the connection electrodes 60 stably electrically connecting the outer electrodes 22 and the extended electrodes 33 can be formed on the cut-away portions 204 and the inclined portions 504 only by sputtering or vacuum deposition. The connection electrodes 60 thus formed can reduce defective formation on the surfaces of the adhesion layers of the connection electrodes 60 of the related art, as well as can reduce manufacturing cost for the connection electrodes 60 and can improve electrode connection stability of the quartz crystal resonator unit 1. The above simple configuration can therefore stabilize frequency characteristics, reduce disconnection risks of the connection electrodes 60 due to defective formation of the connection electrodes 60, and reduce defective connection between the outer electrodes 22 and the excitation electrodes 32, thereby improving resonant frequency stability of the quartz crystal resonator 30.

In the quartz crystal resonator unit 1, the surfaces of the pair of connection electrodes 60 may be covered with plating films.

The plating films can further reduce disconnection risks of the connection electrodes 60 due to electrode separation or the like.

### Second Embodiment

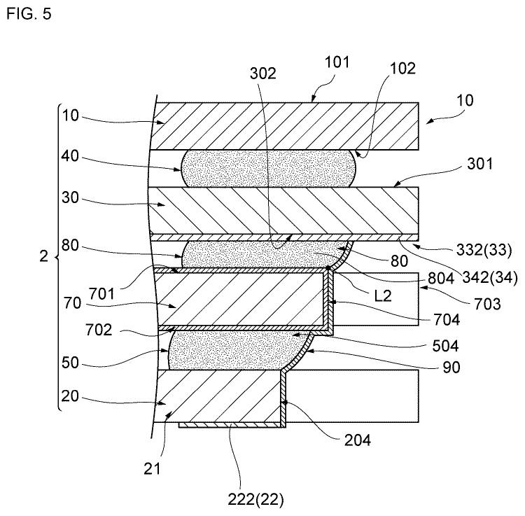

With reference to FIG. 5, description is subsequently made to a configuration of a quartz crystal resonator unit 2 according to the second embodiment. FIG. 5 is an explanatory view on connection relations between electrodes of the quartz crystal resonator unit 2 according to the second embodiment. In the following description, constituent components of the quartz crystal resonator unit 2 according to the second embodiment identical or similar to the constituent components of the quartz crystal resonator unit 1 according to the first embodiment will be denoted by the same or similar reference signs according to the first embodiment, and will not be repeatedly described in detail. The same or a similar applies to third and fourth embodiments to be described later.

The quartz crystal resonator unit 2 according to the second embodiment is different from the quartz crystal resonator unit 1 according to the first embodiment in that the quartz crystal resonator unit 2 according to the second embodiment further includes a third substrate 70 interposed between the quartz crystal resonator 30 and the second substrate 20.

Examples of the third substrate 70 include a thermistor. The second substrate 20 and the third substrate 70 exemplify a plurality of substrates provided adjacent to the second principal surface of the quartz crystal body 31. The third substrate 70 includes a third substrate body 71. The third substrate body 71 has a plate shape. The third substrate body 71 includes a principal surface 701 and a principal surface 702 provided on respective sides in a thickness direction of the plate shape, and an outer peripheral surface 703 constituting a side surface of the plate shape. The outer peripheral surface 703 includes two cut-away portions 704 provided at corner portions corresponding to the pair of extended end portions 34, and an outer peripheral surface portion connected to the two cut-away portions 704.

The principal surface 701 of the third substrate 70 and the second principal surface 302 of the quartz crystal resonator 30 interpose a third adhesion layer 80. The principal surface 702 of the third substrate 70 and the principal surface 201 of the second substrate 20 interpose the second adhesion layer 50. The third substrate 70 is bonded to the quartz crystal resonator 30 and the second substrate 20 by the third adhesion layer 80 and the second adhesion layer 50, respectively.

The third adhesion layer 80 includes two inclined portions 804 corresponding to the two cut-away portions 704 in the outer peripheral surface 703 of the third substrate 70, and a connection portion connected to the two inclined portions 804. As illustrated in FIG. 5, each of the inclined portions 804 has a surface inclined toward an outer side portion of the third substrate 70 from a ridge portion L2 between the cut-away portion 704 and a principal surface 701 of the third substrate 70. The inclined portions 804 are formed in the same or a similar manner to formation of the inclined portions 504.

In plan view of the principal surface 702 of the third substrate 70 in the assembled state, the cut-away portions 704 of the third substrate 70 expose the inclined portions 804 of the third adhesion layer 80 and the extended end portions 34 of the extended electrodes 33. In plan view of the principal surface 202 of the second substrate 20, the cut-away portions 204 of the second substrate 20 expose the inclined portions 504 of the second adhesion layer 50, part of the principal surface 702 of the third substrate 70, the cut-away portions 704 of the third substrate 70, the inclined portions 804 of the third adhesion layer 80, and the extended end portions 34 of the extended electrodes 33.

In this case, connection electrodes 90 are each formed on the cut-away portion 204 of the second substrate 20, the inclined portion 504 of the second adhesion layer 50, part of the principal surface 702 of the third substrate 70, the cut-away portion 704 of the third substrate 70, and the inclined portion 804 of the third adhesion layer 80, so as to electrically connect the outer electrode 22 and the extended end portion 34 of the extended electrode 33. As a result, the outer electrodes 22 on the second substrate 20 are electrically connected to the excitation electrodes 32 of the quartz crystal resonator 30 via the connection electrodes 90 and the extended electrodes 33. The connection electrodes 90 are formed in the same or a similar manner to formation of the connection electrodes 60.

According to the second embodiment, the quartz crystal resonator unit 2 thus configured can achieve the effects according to the first embodiment, as well as achieve frequency adjustment with narrow tolerance by forming the electrodes and executing frequency adjustment after laminating members other than the first substrate 10 in the quartz crystal resonator unit 2 incorporating the thermistor.

### Third Embodiment

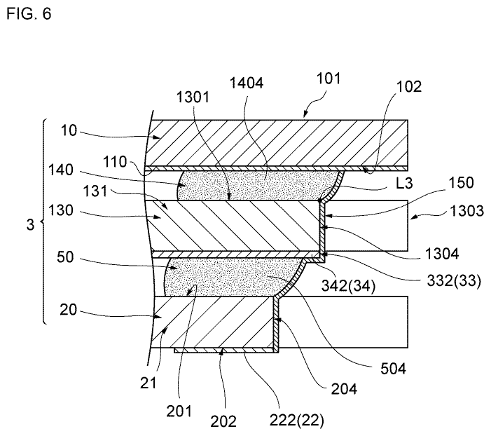

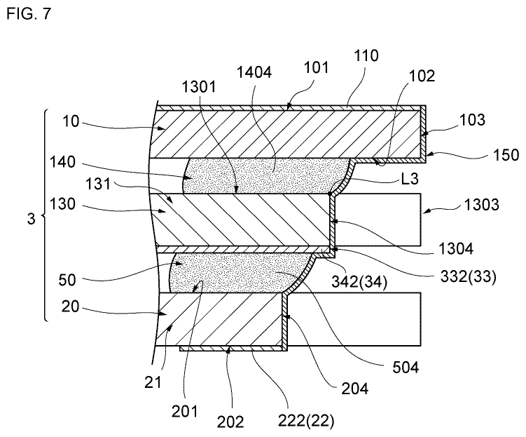

With reference to FIGS. 6 and 7, description is subsequently made to a configuration of a quartz crystal resonator unit 3 according to the third embodiment. FIG. 6 is an explanatory view on connection relations between electrodes of the quartz crystal resonator unit 3 according to the third embodiment. FIG. 7 is an explanatory view on modified disposition of a shield electrode on the first substrate 10 of the quartz crystal resonator unit 3 according to the third embodiment.

The quartz crystal resonator unit 3 according to the third embodiment is different from the quartz crystal resonator unit 1 according to the first embodiment in formation of a shield electrode 110 entirely on the principal surface 102 of the first substrate 10 according to the third embodiment (see FIG. 6) and a configuration of a quartz crystal resonator 130.

The quartz crystal resonator 130 includes a quartz crystal body 131. The quartz crystal body 131 has a plate shape. The quartz crystal body 131 includes a principal surface 1301 and a principal surface 1302 provided on respective sides in a thickness direction of the plate shape, and an outer peripheral surface 1303 constituting a side surface of the plate shape. The outer peripheral surface 1303 includes two cut-away portions 1304 provided at corner portions corresponding to the pair of extended end portions 34, and an outer peripheral surface portion connected to the two cut-away portions 1304.

The principal surface 1301 of the quartz crystal resonator 130 and the principal surface 102 of the first substrate 10 interpose a first adhesion layer 140. The first adhesion layer 140 bonds the quartz crystal resonator 130 to the first substrate 10.

The first adhesion layer 140 includes two inclined portions 1404 corresponding to the two cut-away portions 1304 in the outer peripheral surface 1303 of the quartz crystal resonator 130, and a connection portion connected to the two inclined portions 1404. As illustrated in FIG. 6, each of the inclined portions 1404 has a surface inclined toward an outer side portion of the quartz crystal body 131 from a ridge portion L3 between the cut-away portion 1304 and the principal surface 1301 of the quartz crystal resonator 130. The inclined portions 1404 are formed in the same or a similar manner to formation of the inclined portions 504.

In plan view of the principal surface 1302 of the quartz crystal body 131 in the assembled state, the cut-away portions 1304 of the quartz crystal body 131 expose the inclined portions 1404 of the first adhesion layer 40 and part of the shield electrode 110 on the first substrate 10. In plan view of the principal surface 202 of the second substrate 20, the cut-away portions 204 of the second substrate 20 expose the inclined portions 504 of the second adhesion layer 50, the extended end portions 34 of the extended electrodes 33 of the quartz crystal resonator 130, the cut-away portions 1304 of the quartz crystal resonator 130, the inclined portions 1404 of the first adhesion layer 140, and part of the shield electrode 110 on the first substrate 10.

In this case, connection electrodes 150 are each formed on the cut-away portion 204 of the second substrate 20, the inclined portion 504 of the second adhesion layer 50, the extended end portion 34 of the extended electrode 33 of the quartz crystal resonator 130, the cut-away portion 1304 of the quartz crystal resonator 130, and the inclined portion 1404 of the first adhesion layer 140, so as to electrically connect the outer electrode 22, the extended electrode 33, and the excitation electrode 32 to the shield electrode 110. As a result, the connection electrodes 150 can electrically connect the outer electrodes 22, the extended electrodes 33, and the excitation electrodes 32 to the shield electrode 110. The connection electrodes 150 are formed in the same or a similar manner to formation of the connection electrodes 60.

According to the third embodiment, the quartz crystal resonator unit 3 thus configured can achieve the effects according to the first embodiment, as well as cause the shield electrode 110 to cancel influences of electromagnetic wave noise on the quartz crystal resonator unit 3, so that the quartz crystal resonator unit 3 is applicable to an oscillator and the like.

The shield electrode 110 may be formed on the principal surface 101 of the first substrate 10 as illustrated in FIG. 7 instead of being formed on the principal surface 102 of the first substrate 10. In this case, the connection electrodes 150 are each provided on the cut-away portion 204 of the second substrate 20, the inclined portion 504 of the second adhesion layer 50, the extended end portion 34 of the extended electrode 33 of the quartz crystal resonator 130, the cut-away portion 1304 of the quartz crystal resonator 130, the inclined portion 1404 of the first adhesion layer 140, and part of the outer peripheral surface of the first substrate 10, so as to electrically connect the outer electrode 22, the extended electrode 33, and the excitation electrode 32 to the shield electrode 110.

### Fourth Embodiment

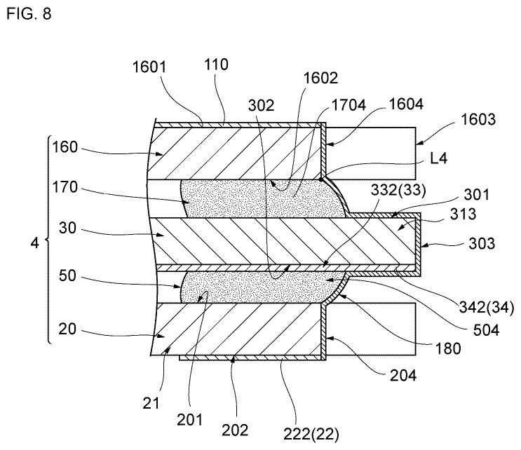

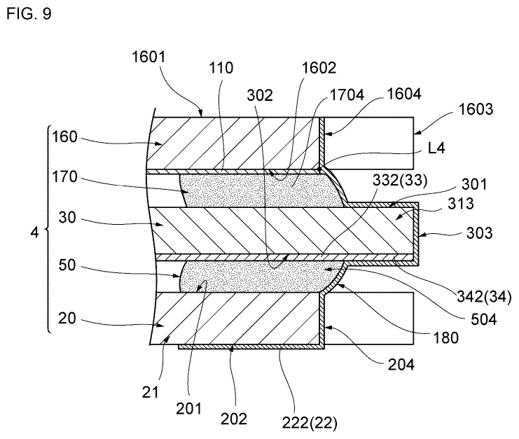

With reference to FIGS. 8 and 9, description is subsequently made to a configuration of a quartz crystal resonator unit 4 according to the fourth embodiment. FIG. 8 is an explanatory view on connection relations between electrodes of the quartz crystal resonator unit 4 according to the fourth embodiment. FIG. 9 is an explanatory view on modified disposition of a shield electrode on a first substrate 160 of the quartz crystal resonator unit 4 according to the fourth embodiment.

The quartz crystal resonator unit 4 according to the fourth embodiment is different from the quartz crystal resonator unit 1 according to the first embodiment in a configuration of the first substrate 160 according to the fourth embodiment.

The first substrate 160 includes a first substrate body 161. The first substrate body 161 has a plate shape. The first substrate body 161 includes a principal surface 1601 and a principal surface 1602 provided on respective sides in a thickness direction of the plate shape, and an outer peripheral surface 1603 constituting a side surface of the plate shape. FIG. 8 exemplifies a case where the shield electrode 110 is formed entirely on the principal surface 1601. The outer peripheral surface 1603 includes two cut-away portions 1604 provided at corner portions corresponding to the pair of extended end portions 34, and an outer peripheral surface portion connected to the two cut-away portions 1604.

The principal surface 1602 of the first substrate body 161 and the first principal surface 301 of the quartz crystal resonator 30 interpose a first adhesion layer 170. The first adhesion layer 170 bonds the first substrate 160 to the quartz crystal resonator 30.

The first adhesion layer 170 includes two inclined portions 1704 corresponding to the two cut-away portions 1604 in the outer peripheral surface 1603 of the first substrate 160, and a connection portion connected to the two inclined portions 1704. As illustrated in FIG. 8, each of the inclined portions 1704 has a surface inclined toward an outer side portion of the first substrate body 161 from a ridge portion L4 between the cut-away portion 1604 and the principal surface 1602 of the first substrate 160. The inclined portions 1704 are formed in the same or a similar manner to formation of the inclined portions 504.

In plan view of the principal surface 1601 of the first substrate 160 in the assembled state, the cut-away portions 1604 expose the inclined portions 1704 of the first adhesion layer 170 and part of the peripheral edge portion 312 of the quartz crystal body 31.

In this case, connection electrodes 180 are each formed on the cut-away portion 204 of the second substrate 20, the inclined portion 504 of the second adhesion layer 50, the extended end portion 34 of the extended electrode 33 of the quartz crystal resonator 30, part of the peripheral edge portion 312 of the quartz crystal body 31, the inclined portion 1704 of the first adhesion layer 170, and the cut-away portion 1604 of the first substrate 160, so as to electrically connect the outer electrode 22, the extended electrode 33, and the excitation electrode 32 to the shield electrode 110. As a result, the connection electrodes 180 can electrically connect the outer electrodes 22, the extended electrodes 33, and the excitation electrodes 32 to the shield electrode 110. The connection electrodes 180 are formed in a part between the second substrate 20 and the quartz crystal resonator 30 in the same or a similar manner to formation of the connection electrodes 60. The connection electrodes 180 can be formed in a part between the first substrate 160 and the quartz crystal resonator 30 by applying sputtering or vacuum deposition toward the principal surface 1601 of the first substrate 160.

According to the fourth embodiment, the quartz crystal resonator unit 4 thus configured can achieve the effects according to the first embodiment, as well as cause the shield electrode 110 to cancel influences of electromagnetic wave noise on the quartz crystal resonator unit 4, so that the quartz crystal resonator unit 4 is applicable to an oscillator and the like.

The shield electrode 110 may be formed on the principal surface 1602 of the first substrate 160 as illustrated in FIG. 9 instead of being formed on the principal surface 1601 of the first substrate 160. In this case, the connection electrodes 180 are each formed on the cut-away portion 204 of the second substrate 20, the inclined portion 504 of the second adhesion layer 50, the extended end portion 34 of the extended electrode 33 of the quartz crystal resonator 30, part of the peripheral edge portion 312 of the quartz crystal body 31, the inclined portion 1704 of the first adhesion layer 170, the cut-away portion 1604 of the first substrate 160, and part of the outer peripheral surface of the first substrate 160, so as to electrically connect the outer electrode 22, the extended electrode 33, and the excitation electrode 32 to the shield electrode 110.

### Fifth Embodiment

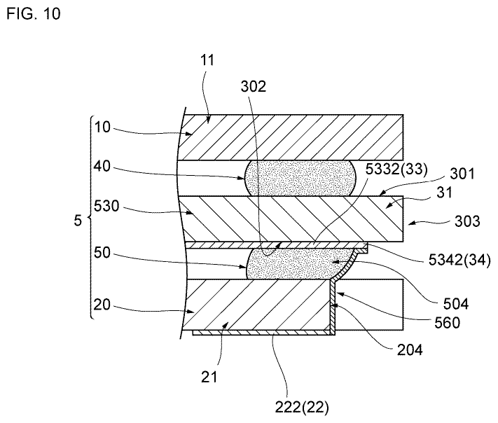

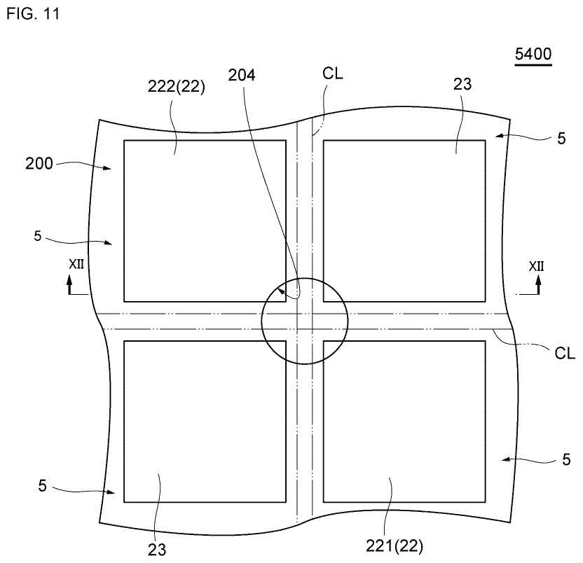

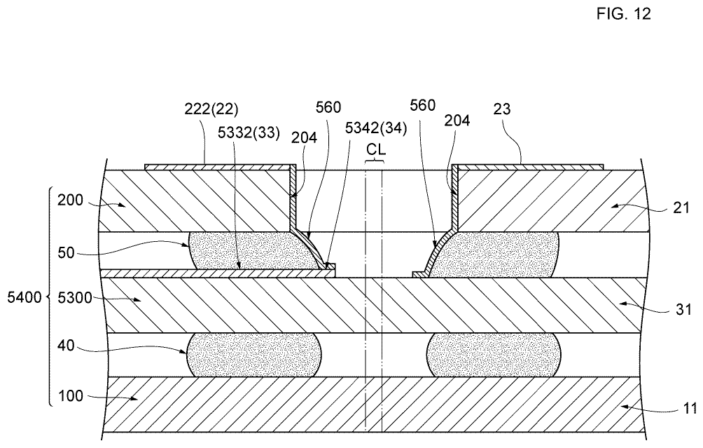

With reference to FIGS. 10 to 12, description is subsequently made to a configuration of a quartz crystal resonator unit 5 and a method of manufacturing the quartz crystal resonator unit 5 according to the fifth embodiment. FIG. 10 is an explanatory view on connection relations between electrodes of the quartz crystal resonator unit 5 according to the fifth embodiment. FIGS. 11 and 12 are explanatory views on the method of manufacturing the quartz crystal resonator unit according to the fifth embodiment. FIG. 12 is a sectional view taken along line XII-XII of the wafer adhesion body 400 illustrated in FIG. 11.

The quartz crystal resonator unit 5 according to the fifth embodiment is different from the quartz crystal resonator unit 1 according to the first embodiment in a configuration of a quartz crystal resonator 530 according to the fifth embodiment.

As illustrated in FIG. 10, the quartz crystal resonator unit 5 includes a second extended electrode 5332 provided with a second extended end portion 5342 and positioned distant from the outer peripheral surface 303 of the quartz crystal body 31. Though not shown, the quartz crystal resonator unit 5 includes a first extended electrode provided with a first extended end portion and positioned distant from the outer peripheral surface 303 of the quartz crystal body 31. That is, the pair of extended electrodes 33 including the pair of extended end portions 34 are positioned on the second principal surface 302 of the quartz crystal body 31 and distant from the outer peripheral surface 303 of the quartz crystal body 31.

A pair of connection electrodes 560 are positioned distant from the outer peripheral surface 303 of the quartz crystal body 31. The pair of connection electrodes 560 are provided on the cut-away portions 204 of the second substrate 20 and the inclined portions 504 of the second adhesion layer 50. As illustrated in FIG. 10, one of the connection electrodes 560 electrically connected to the second outer electrode 222 is provided also on the second extended end portion 5342 of the second extended electrode 5332. Though not shown, another one of the connection electrodes 560 electrically connected to the first outer electrode 221 is provided also on the first extended end portion of the first extended electrode. That is, the pair of connection electrodes 560 are provided on the pair of extended end portions 34 of the pair of extended electrodes 33 of the quartz crystal resonator 530. In plan view of the first principal surface 301 and the second principal surface 302 of the quartz crystal resonator 530, end surfaces of the pair of extended end portions 34 are exemplarily overlapped with end surfaces of the pair of connection electrodes 560. However, the configuration is not limited to this disposition. In plan view, the end surfaces of the pair of connection electrodes 560 may alternatively be provided closer to the outer peripheral surface 303 than the end surfaces of the pair of extended end portions 34. That is, the pair of connection electrodes 560 may cover the end surfaces of the pair of extended end portions 34 and may be provided also on the second principal surface 302 of the quartz crystal body 31. Still alternatively, the end surfaces of the pair of connection electrodes 560 may be provided closer to the second adhesion layer 50 than the end surfaces of the pair of extended end portions 34.

In summary, in plan view of the first principal surface 301 and the second principal surface 302 of the quartz crystal resonator 530, the electrodes formed on surfaces of the second substrate 20 and the quartz crystal resonator 530 have ends positioned inside an outer shape of the quartz crystal resonator 530.

As illustrated in FIGS. 11 and 12, the outer electrodes 22 and the outer electrodes 23 formed in a piezoelectric wafer 5300 of a wafer adhesion body 5400 are distant from each other. The wafer adhesion body 5400 is cut along cut lines CL to be diced into individual quartz crystal resonator units 5. In this case, the pair of connection electrodes 560 and the pair of extended electrodes 33 formed on the wafer adhesion body 5400 are distant from the cut lines CL. That is, the quartz crystal resonator units 5 positioned adjacent to each other and interposing the cut lines CL are electrically insulated from each other.

The present embodiment exemplifies the configuration in which the pair of extended electrodes are both distant from the outer peripheral surface of the quartz crystal body. Alternatively, at least one of the pair of extended electrodes has only to be distant from the outer peripheral surface of the quartz crystal body. Similarly, at least one of the pair of connection electrodes has only to be distant from the outer peripheral surface of the quartz crystal body.

### Sixth Embodiment

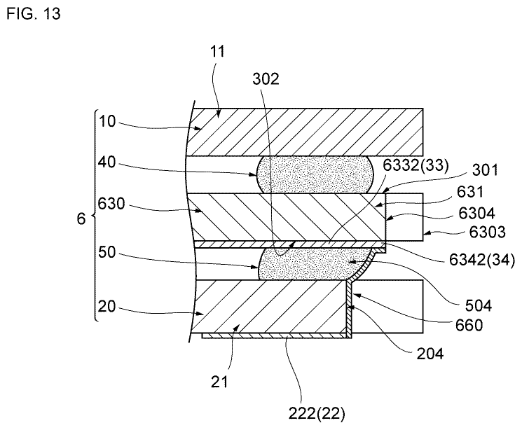

With reference to FIG. 13, description is subsequently made to a configuration of a quartz crystal resonator unit 6 according to the sixth embodiment. FIG. 13 is an explanatory view on connection relations between electrodes of the quartz crystal resonator unit 6 according to the sixth embodiment.

The quartz crystal resonator unit 6 according to the sixth embodiment is different from the quartz crystal resonator unit 1 according to the first embodiment in a configuration of a quartz crystal resonator 630 according to the sixth embodiment.

The quartz crystal resonator 630 includes a quartz crystal body 631 having an outer peripheral surface 6303 provided with cut-away portions 6304. The quartz crystal resonator unit 6 includes a second extended electrode 6332 provided with a second extended end portion 6342 and positioned distant from the outer peripheral surface 6303 of the quartz crystal body 631. Though not shown, the quartz crystal resonator unit 6 includes a first extended electrode provided with a first extended end portion and positioned distant from the outer peripheral surface 6303 of the quartz crystal body 631 in a similar manner. That is, the pair of extended end portions 34 of the pair of extended electrodes 33 are positioned on the second principal surface 302 of the quartz crystal body 631 and distant from the outer peripheral surface 6303 of the quartz crystal body 631.

A pair of connection electrodes 660 are positioned distant from the outer peripheral surface 6303 of the quartz crystal body 631. The pair of connection electrodes 660 are provided on the cut-away portions 204 of the second substrate 20 and the inclined portions 504 of the second adhesion layer 50. As illustrated in FIG. 13, one of the connection electrodes 660 electrically connected to the second outer electrode 222 is provided also on the second extended end portion 6342 of the second extended electrode 6332. Though not shown, another one of the connection electrodes 660 electrically connected to the first outer electrode 221 is provided also on the first extended end portion of the first extended electrode. That is, the pair of connection electrodes 660 are provided on the pair of extended end portions 34 of the pair of extended electrodes 33 of the quartz crystal resonator 630. In plan view of the first principal surface 301 and the second principal surface 302 of the quartz crystal resonator 630, the end surfaces of the pair of extended end portions 34 and end surfaces of the pair of connection electrodes 660 are exemplarily overlapped with the cut-away portions 6304. However, the configuration is not limited to this disposition. In plan view, the end surfaces of the pair of connection electrodes 660 may be overlapped with the end surfaces of the pair of extended end portions 34 as well as may be positioned distant from the cut-away portions 6304. Alternatively, the end surfaces of the pair of connection electrodes 660 may be positioned distant from the end surfaces of the pair of extended end portions 34 as well as may be positioned distant from the cut-away portions 6304. For example, the end surfaces of the pair of connection electrodes 660 may be provided closer to the cut-away portions 6304 than the end surfaces of the pair of extended end portions 34, or may be provided closer to the second adhesion layer 50 than the end surfaces of the pair of extended end portions 34.

In summary, in plan view of the first principal surface 301 and the second principal surface 302 of the quartz crystal resonator 630, the electrodes formed on surfaces of the second substrate 20 and the quartz crystal resonator 630 have the ends positioned inside an outer shape of the quartz crystal resonator 630.

According to the sixth embodiment, the quartz crystal resonator unit 6 thus configured can achieve the effects according to the fifth embodiment. Furthermore, the extended end portions 34 of the extended electrodes 33 of the quartz crystal resonator units 6 adjacent to each other on the wafer adhesion body are positioned physically distant from each other by the cut-away portions 6304, thereby preventing electrical connection between the extended electrodes 33 and the connection electrodes 660 of the quartz crystal resonator units 6 adjacent to each other on the wafer adhesion body across the cut lines CL due to manufacturing errors.

### Seventh Embodiment

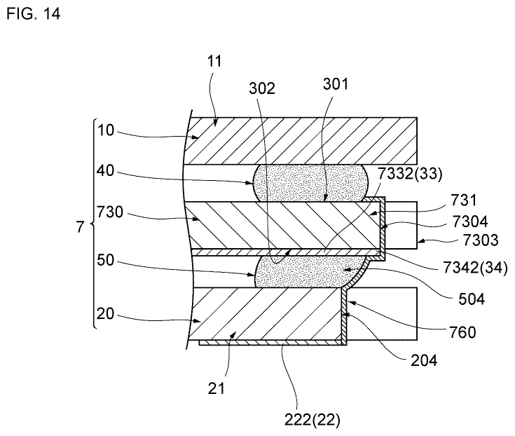

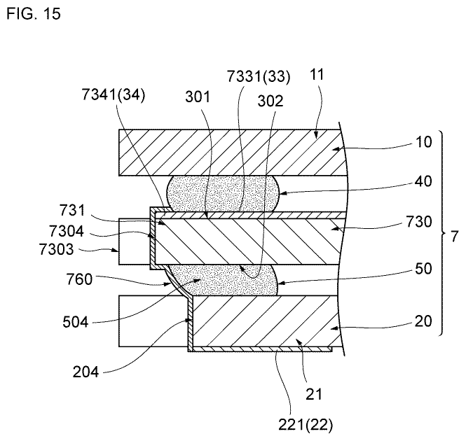

With reference to FIGS. 14 and 15, description is subsequently made to a configuration of a quartz crystal resonator unit 7 and a method of manufacturing the quartz crystal resonator unit 7 according to the seventh embodiment. FIGS. 14 and 15 are explanatory views on connection relations between electrodes of the quartz crystal resonator unit 7 according to the seventh embodiment.

The quartz crystal resonator unit 7 according to the seventh embodiment is different from the quartz crystal resonator unit 1 according to the first embodiment in a configuration of a quartz crystal resonator 730 according to the seventh embodiment.

The quartz crystal resonator 730 includes a quartz crystal body 731 having an outer peripheral surface 7303 provided with cut-away portions 7304.

As illustrated in FIG. 14, the quartz crystal resonator unit 7 includes a second extended electrode 7332 provided with a second extended end portion 7342 and positioned distant from the outer peripheral surface 7303 of the quartz crystal body 731. The second extended end portion 7342 of the second extended electrode 7332 is positioned on the second principal surface 302 of the quartz crystal body 731 and distant from the outer peripheral surface 7303 of the quartz crystal body 731. In plan view of the first principal surface 301 and the second principal surface 302 of the quartz crystal resonator 730, an end surface of the second extended end portion 7342 is exemplarily overlapped with the cut-away portion 7304. However, the configuration is not limited to this disposition. The end surface of the second extended end portion 7342 may be positioned distant from the cut-away portion 7304 or on the cut-away portion 7304.

As illustrated in FIG. 15, the quartz crystal resonator unit 7 includes a first extended electrode 7331 provided with a first extended end portion 7341 and positioned distant from the outer peripheral surface 7303 of the quartz crystal body 731 in a similar manner. The first extended end portion 7341 of the first extended electrode 7331 is positioned on the first principal surface 301 of the quartz crystal body 731 and distant from the outer peripheral surface 7303 of the quartz crystal body 731. In plan view of the first principal surface 301 and the second principal surface 302 of the quartz crystal resonator 730, an end surface of the first extended end portion 7341 is exemplarily overlapped with the cut-away portion 7304. However, the configuration is not limited to this disposition. The end surface of the first extended end portion 7341 may be positioned distant from the cut-away portion 7304 or on the cut-away portion 7304.

A pair of connection electrodes 760 are positioned distant from the outer peripheral surface 7303 of the quartz crystal body 731. As illustrated in FIG. 14, one of the pair of connection electrodes 760 electrically connected to the second outer electrode 222 is provided across the cut-away portion 204 of the second substrate 20, the inclined portion 504 of the second adhesion layer 50, the second extended end portion 7342 of the second extended electrode 7332 of the quartz crystal resonator 730, the cut-away portion 7304 of the quartz crystal resonator 730, and the first principal surface 301 of the quartz crystal resonator 730. The one of the connection electrodes 760 electrically connected to the second outer electrode 222 has an end portion exemplarily provided closer to the cut-away portion 7304 than the first adhesion layer 40 on the first principal surface 301 of the quartz crystal resonator 730. As illustrated in FIG. 15, another one of the pair of connection electrodes 760 electrically connected to the first outer electrode 221 is provided across the cut-away portion 204 of the second substrate 20, the inclined portion 504 of the second adhesion layer 50, the second principal surface 302 of the quartz crystal resonator 730, the cut-away portion 7304 of the quartz crystal resonator 730, and the first principal surface 301 of the quartz crystal resonator 730. The other one of the connection electrodes 760 electrically connected to the first outer electrode 221 has an end portion exemplarily provided closer to the cut-away portion 7304 than the first adhesion layer 40 on the first principal surface 301 of the quartz crystal resonator 730.

According to the seventh embodiment, the quartz crystal resonator unit 7 thus configured can achieve the effects according to the sixth embodiment, as well as electrically connect the first extended electrode 7331 and the connection electrode 760 without routing the first extended end portion 7341 of the first extended electrode 7331 from the first principal surface 301 to the second principal surface 302 of the quartz crystal resonator 730.

The embodiments have been described above for easier comprehension of the present disclosure and not for limited interpretation of the present disclosure. The present disclosure can be modified or improved without departing from the gist of the disclosure, and also includes equivalents thereof. That is, any appropriate modifications in design by those skilled in the art are also included in the scope of the present disclosure as long as such modifications exhibit the features of the present disclosure. For example, each element, as well as disposition, material, condition, shape, size, and the like thereof according to each of the embodiments are not limited to the above exemplification but may be modified as appropriate. The embodiments are provided exemplarily, any partial replacement or combination between configurations exemplified in different embodiments are obviously applicable, and such replacement or combination are also included in the scope of the present disclosure as long as the replacement or combination exhibits the features of the present disclosure.

### REFERENCE SIGNS LIST

1, 2, 3, 4, 5, 6, 7 quartz crystal resonator unit
10 first substrate
20 second substrate
22 outer electrode
30 quartz crystal resonator
31 quartz crystal body
32 excitation electrode
33 extended electrode
34 extended end portion
40 first adhesion layer
50 second adhesion layer
60 connection electrode
204 cut-away portion
504 inclined portion

1. A piezoelectric resonator unit comprising:
a piezoelectric resonator including a piezoelectric layer having a first principal surface and a second principal surface facing each other in a thickness direction of the piezoelectric layer, a first excitation electrode on the first principal surface, a second excitation electrode on the second principal surface, a first extended electrode electrically connected to the first excitation electrode and extended to a peripheral edge portion of the first principal surface of the piezoelectric layer, and a second extended electrode electrically connected to the second excitation electrode and extended to a peripheral edge portion of the second principal surface of the piezoelectric layer;
a first substrate adjacent to the first principal surface of the piezoelectric layer;
a first adhesion layer interposed between the first substrate and the piezoelectric layer;
a second substrate adjacent to the second principal surface of the piezoelectric layer; and
a second adhesion layer interposed between the second substrate and the piezoelectric layer, wherein
the second substrate includes a first outer electrode in a peripheral edge portion on a surface opposite from the piezoelectric layer,
in plan view of the surface of the second substrate opposite from the piezoelectric layer, the second substrate includes a first cut-away portion exposing a first inclined portion of the second adhesion layer expanding toward an outer side portion of the second substrate and a first extended end portion of one of the first extended electrode or the second extended electrode; and
a first connection electrode on the first inclined portion of the second adhesion layer and the first cut-away portion of the second substrate that electrically connects the first outer electrode and the first extended end portion of the one of the first extended electrode or the second extended electrode.

2. The piezoelectric resonator unit according to claim 1, wherein the first connection electrode and the first extended end portion of the one of the first extended electrode or the second extended electrode each have a surface covered with a plating film.

3. The piezoelectric resonator unit according to claim 1, wherein
the first extended end portion is of the first extended electrode,
the first connection electrode on the first inclined portion of the second adhesion layer and the first cut-away portion of the second substrate electrically connect the first outer electrode and the first extended end portion of the first extended electrode,
the second substrate includes a second outer electrode in the peripheral edge portion on the surface opposite from the piezoelectric layer,
in the plan view of the surface of the second substrate opposite from the piezoelectric layer, the second substrate includes a second cut-away portion exposing a second inclined portion of the second adhesion layer expanding toward the outer side portion of the second substrate and a second extended end portion of the second extended electrode, and
the piezoelectric resonator unit further includes a second connection electrode on the second inclined portion of the second adhesion layer and the second cut-away portion of the second substrate that electrically connects the second outer electrode and the second extended end portion of the second extended electrode.

4. The piezoelectric resonator unit according to claim 3, wherein
the first connection electrode and the first extended end portion of the first extended electrode each have a surface covered with a first plating film, and
the second connection electrode and the second extended end portion of the second extended electrode each have a surface covered with a second plating film.

5. The piezoelectric resonator unit according to claim 1, further comprising:
a shield electrode entirely on a surface of the first substrate facing the piezoelectric layer or a surface opposite from the piezoelectric layer,
in plan view of the second principal surface of the piezoelectric layer, the piezoelectric layer includes a piezoelectric cut-away portion exposing a second inclined portion of the first adhesion layer expanding toward an outer side portion of the piezoelectric layer and a peripheral edge portion of the shield electrode,
in the plan view of the surface of the second substrate opposite from the piezoelectric layer, the second cut-away portion exposes the first inclined portion of the second adhesion layer, the first extended end portion of the one of the first extended electrode or the second extended electrode, the second inclined portion of the first adhesion layer, and the peripheral edge portion of the shield electrode, and
the first connection electrode is on the second cut-away portion of the second substrate, the first inclined portion of the second adhesion layer, the piezoelectric cut-away portion of the piezoelectric layer, and the second inclined portion of the first adhesion layer.

6. The piezoelectric resonator unit according to claim 1, further comprising:
a shield electrode on a surface of the first substrate facing the piezoelectric layer or a surface opposite from the piezoelectric layer,
in plan view of the surface of the first substrate opposite from the piezoelectric layer, the first substrate includes a second cut-away portion exposing a second inclined portion of the first adhesion layer expanding toward an outer side portion of the first substrate, and a peripheral edge portion of the piezoelectric layer corresponding to the first cut-away portion of the second substrate, and
the connection electrode is on the first cut-away portion of the second substrate, the first inclined portion of the second adhesion layer, an outer peripheral surface of the piezoelectric layer, the second cut-away portion of the first substrate, and the second inclined portion of the first adhesion layer.

7. A piezoelectric resonator unit comprising:
a piezoelectric resonator including a piezoelectric layer having a first principal surface and a second principal surface facing each other in a thickness direction of the piezoelectric layer, a first excitation electrode on the first principal surface, a second excitation electrode on the second principal surface, a first extended electrode electrically connected to the first excitation electrode and extended to a peripheral edge portion of the first principal surface of the piezoelectric layer, and a second extended electrode electrically connected to the second excitation electrode and extended to a peripheral edge portion of the second principal surface of the piezoelectric layer;
a first substrate adjacent to the first principal surface of the piezoelectric layer;
a first adhesion layer interposed between the first substrate and the piezoelectric layer;
a second substrate adjacent to the second principal surface of the piezoelectric layer;
a third substrate adjacent to the second principal surface of the piezoelectric layer, the third substrate positioned closer to the second principal surface of the piezoelectric layer than the second substrate;
a third adhesion layer interposed between the third substrate and the piezoelectric layer; and
a second adhesion layer interposed between the second substrate and the third substrate, wherein
the second substrate includes a first outer electrode in a peripheral edge portion on a surface opposite from the piezoelectric layer,
in plan view of a surface of the third substrate opposite from the piezoelectric layer, the third substrate includes a first cut-away portion exposing a first inclined portion of the third adhesion layer expanding toward an outer side portion of the third substrate and a first extended end portion of one of the first extended electrode or the second extended electrode,
in plan view of the surface of the second substrate opposite from the piezoelectric layer, the second substrate includes a second cut-away portion exposing a second inclined portion of the second adhesion layer expanding toward an outer side portion of the second substrate, the first extended end portion of the one of the first extended electrode or the second extended electrode, the first inclined portion of the third adhesion layer, and the first cut-away portion of the third substrate; and
a first connection electrode on the second cut-away portion of the second substrate, the second inclined portion of the second adhesion layer, the first cut-away portion of the third substrate, and the first inclined portion of the third adhesion layer that electrically connects the first outer electrode and the first extended end portion of the one of the first extended electrode or the second extended electrode.

8. The piezoelectric resonator unit according to claim 7, further comprising:
a shield electrode entirely on a surface of the first substrate facing the piezoelectric layer or a surface opposite from the piezoelectric layer,
in plan view of the second principal surface of the piezoelectric layer, the piezoelectric layer includes a piezoelectric cut-away portion exposing a third inclined portion of the first adhesion layer expanding toward an outer side portion of the piezoelectric layer and a peripheral edge portion of the shield electrode,
in the plan view of the surface of the second substrate opposite from the piezoelectric layer, the third cut-away portion exposes the second inclined portion of the second adhesion layer, the first extended end portion of the one of the first extended electrode or the second extended electrode, the third inclined portion of the first adhesion layer, and the peripheral edge portion of the shield electrode, and
the first connection electrode is on the second cut-away portion of the second substrate, the second inclined portion of the second adhesion layer, the piezoelectric cut-away portion of the piezoelectric layer, and the third inclined portion of the first adhesion layer.

9. The piezoelectric resonator unit according to claim 7, further comprising:
a shield electrode on a surface of the first substrate facing the piezoelectric layer or a surface opposite from the piezoelectric layer,
in plan view of the surface of the first substrate opposite from the piezoelectric layer, the first substrate includes a third cut-away portion exposing a third inclined portion of the first adhesion layer expanding toward an outer side portion of the first substrate, and a peripheral edge portion of the piezoelectric layer corresponding to the second cut-away portion of the second substrate, and
the connection electrode is on the second cut-away portion of the second substrate, the second inclined portion of the second adhesion layer, an outer peripheral surface of the piezoelectric layer, the third cut-away portion of the first substrate, and the third inclined portion of the first adhesion layer.

10. The piezoelectric resonator unit according to claim 7, wherein the first connection electrode and the first extended end portion of the one of the first extended electrode or the second extended electrode each have a surface covered with a plating film.
